(19) United States
(12) Patent Application Publication
(10) Pub. No.: US 2007/0221940 A1
(43) Pub. Date: Sep. 27, 2007

(54) LED DEVICE AND PRODUCTION METHOD THEREOF

(75) Inventor: Tadahiro Okazaki, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD, Kyoto (JP)

(21) Appl. No.: 11/687,407

(22) Filed: Mar. 16, 2007

(30) Foreign Application Priority Data
Mar. 23, 2006 (JP) 2006-080365

(51) Int. Cl. H01L 33/00; H01L 29/22

(52) U.S. Cl. 257/99

(57) ABSTRACT

An LED device includes an LED chip die-bonded to a frame with a die-bonding material, wherein the die-bonding material contains Ag, a fine white powder, and solder particles. The LED device is superior in both reflectance and bonding strength because of the use of the die-bonding material.

### BACKGROUND OF THE INVENTION

1. Field of the Invention

The present invention relates to an LED device, including an LED chip bonded to the pad of a frame or substrate with a die-bonding material, and a method of producing the LED device.

2. Description of the Background Art

FIG. 4 is a sectional view illustrating an example of a light-emitting device having an LED chip bonded to a frame. As shown in FIG. 4, the LED device X has metal frames 91 and 92, a die-bonding material 95 coated on the bottom surface of a cone-shaped recess 91a formed in the frame 91, and an LED chip 93 mounted on the die-bonding material 95. An electrode 93a is provided on the top surface of the LED chip 93, and the electrode 93a is electrically connected to the frame 92 via a bonding wire 94. The bottom surface of the LED chip 93 in FIG. 4 includes another electrode 93b, and the electrode 93b is bonded to the die-bonding material 95. Typically, the frames 91 and 92 and the LED chip 93 are sealed with an optically transparent resin package (not shown in FIG. 4).

The LED device X is designed to make the LED chip 93 emit light when one of the frames 91 and 92 is connected to ground and the other to a power source, thereby allowing a flow of current. The LED chip 93 emits light in the horizontal direction in FIG. 4 and the light travels in the upward direction as it is reflected by the slanting surface of the recess 91a. Examples of LED devices having an LED chip die-bonded to a frame such as the LED device X include those described in domestic re-publication of PCT international application WO 2002/054503 and Japanese Unexamined Patent Publication 2005-294736.

Ag pastes have been used frequently as the die-bonding material 95 for the reasons of conductivity and cost. However, because the solidified Ag paste is relatively low in reflectance, use of an Ag paste as the die-bonding material 95 often caused petal-like dark shadows during light emission from the LED chip 93. As a result, the light reflected from the solidified Ag paste surface was inadequate, causing deterioration in the light-emitting efficiency of the LED device X.

To solve the problems described above, a white metal powder having superior reflectance such as TiO₂ was added to the Ag paste, but such a conventional method caused new problems of, for example, deterioration in bonding strength and heat-releasing efficiency.

### SUMMARY OF THE INVENTION

In order to overcome the problems described above, preferred embodiments of the present invention provide an LED device using a die-bonding material that is improved in reflectance, bonding strength, and heat-releasing efficiency, and a method of producing an LED device using the die-bonding material.

An LED device according to a first preferred embodiment of the present invention includes an LED chip bonded to the pad of a frame or substrate (hereinafter simply referred to as a frame) with a die-bonding material, wherein the die-bonding material contains Ag and additionally a fine white powder. Preferably, the fine white powder is BN.

In such a configuration, it is possible to compensate for the deterioration in reflectance of Ag with a highly reflective fine white powder and to improve the reflectance from the die-bonding material after die bonding. In particular, a fine white BN powder having a high heat-releasing efficiency results in the improvement of the heat-releasing efficiency of the die-bonding material.

In another preferred embodiment of the present invention, the die-bonding material additionally contains solder particles. In such a configuration, the LED chip and the pad of the frame are tightly bonded to each other by eutectic bonding of the solder particles.

A method of producing an LED device according to a further preferred embodiment of the present invention includes producing an LED device having an LED chip bonded to the pad of a frame with a die-bonding material, wherein the die-bonding material is a paste-like material prepared by mixing Ag powder, a fine white powder, and solder particles in a resin or plastic material (hereinafter referred to as a resin) having a particular viscosity, wherein the solder particles have a specific density greater than that of the resin. The method includes a step of coating the die-bonding material on the pad of the frame in a region larger than the planar size of the LED chip, a step of mounting the LED chip on the coated die-bonding material, and a step of heating the die-bonding material to a temperature higher than the melting point of the solder particles.

In such a production method, because the solder particles have a specific density greater than that of the resin, the solder particles melted by heating sink on the pad of the frame, facilitating eutectic bonding between the solder particles and the pad of the frame. In addition, sedimentation of the solder particles leaves a layer of fine white powder-containing resin on the surface of the die-bonding material. Because most of the resin is vaporized by heating, the surface of the die-bonding material after the heat treatment is covered with the fine white powder having an improved reflectance.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a sectional view illustrating an LED device according to a first preferred embodiment of the present invention.

FIG. 2 is an expanded view illustrating the main components of the LED device shown in FIG. 1.

FIG. 3 is a top view of the LED device shown in FIG. 2.

FIG. 4 is a sectional view illustrating a conventional LED device.

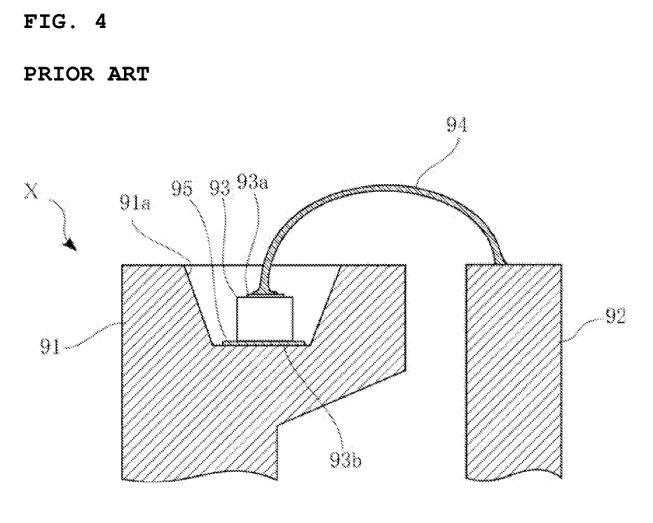

### DETAILED DESCRIPTION OF PREFERRED EMBODIMENTS

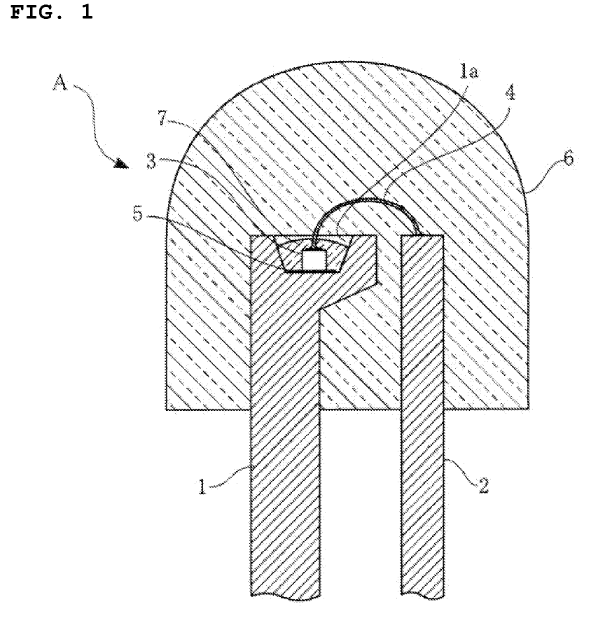

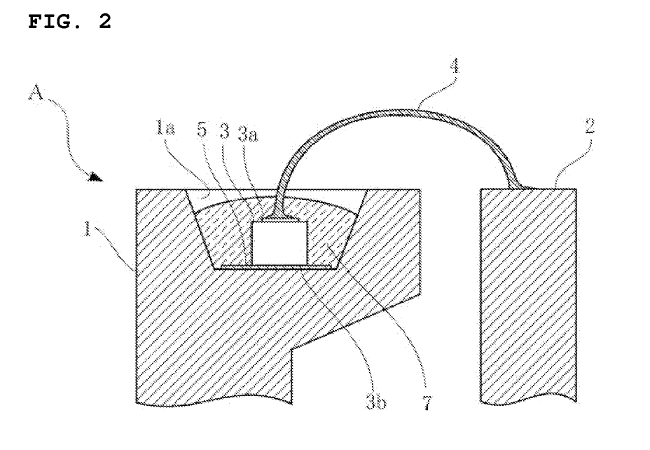

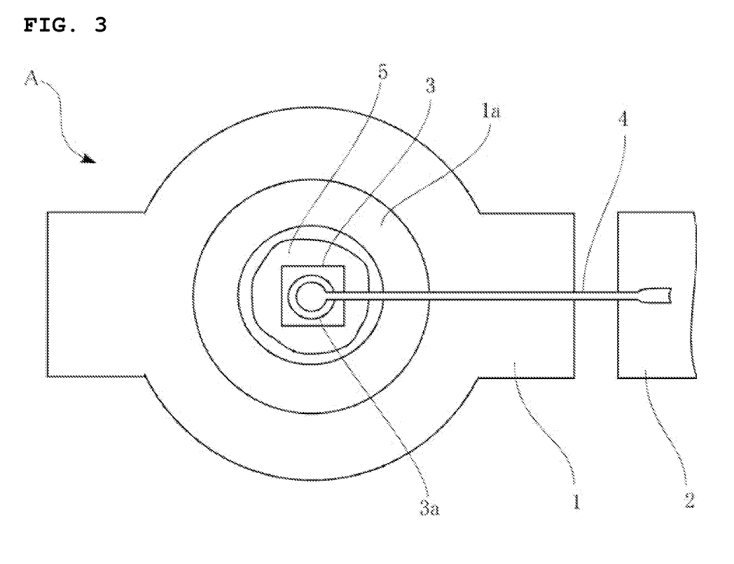

FIG. 1 is a sectional view illustrating a preferred embodiment of the LED device of the present invention. The LED device A shown in FIG. 1 preferably includes metal frames 1 and 2, an LED chip 3 die-bonded to the frame 1, and a dome-shaped transparent resin 6 covering portions of the frames 1 and 2. FIG. 2 is an expanded sectional view illustrating the main component region of the device shown in FIG. 1, and FIG. 3 is a top view illustrating the device shown in FIG. 2. Hereinafter, the LED device A will be described with reference to FIGS. 1 to 3.

The frames 1 and 2 are separated by a particular gap, and extend in the downward direction in FIG. 1, and the distal ends thereof are connected respectively to an external power unit supplying power to the LED chip 3 and to ground. As shown in FIG. 2, the frame 1 is designed to have a larger sectional area in an upper region close to the top than that of a lower region below the top. As shown in FIGS. 2 and 3, the frame 1 has a cone-shaped recess 1a formed, for example, by press molding. As shown in FIG. 2, a die-bonding material 5 is coated on a bottom surface of the recess 1a in a region wider than a bottom surface of the LED chip 3 for installing the LED chip 3.

The die-bonding material 5 is a paste-like material preferably prepared by dispersing Ag powder, fine white BN powder, and solder particles in a solvent epoxy resin. As for the composition of the die-bonding material 5, the ratio is preferably about 40% solder particles, about 36% Ag powder, about 12% fine white BN powder, and the balance the epoxy resin, for example. The particle diameter of the Ag powder is preferably about 5 μm to about 30 μm, and the solder particles are preferably Sn—Pb, Sn—Ag, Sn—Ag—Cu, or the like. The epoxy resin preferably has a viscosity of about 500 cP to about 1,000 cP and a specific density smaller than that of the solder particles.

As shown in FIG. 2, the LED chip 3 has a side wall emitting light, an electrode 3a provided on the top surface, and a metal electrode 3b provided along the entire bottom surface. The electrode 3a is electrically connected to the frame 2 with a bonding wire 4. On the other hand, the bottom surface of the LED chip 3 is bonded to the Ag-containing die-bonding material 5 and thus electrically connected to the frame 1.

As shown in FIG. 1, the frames 1 and 2 are covered with a transparent resin 6 such as epoxy resin. The transparent resin 6 protects the LED chip 3 and the bonding wire 4 from the external environment, such as moisture, gas and dust, and mechanical stresses such as vibration and impact. However, the transparent resin 6 is relatively high in rigidity and may break the LED chip 3 and the bonding wire 4, for example, when expanded by heat. For that reason, as shown in FIG. 2, the recess 1a is filled with a relatively soft transparent resin 7 such as silicone resin or an epoxy resin that is softer than resin 6 for protection of the LED chip 3 and the bonding wire 4.

The method of producing such an LED device A will be described below.

First, a recess 1a is formed on the frame 1 by, for example, press molding, and then, a die-bonding material 5 is coated on the bottom surface of the recess 1a in a region wider than a bottom surface of the LED chip 3. The LED chip 3 is mounted on the coated die-bonding material 5, and the die-bonding material 5 is heated to a temperature higher than the melting point of the solder particles. The solder particles melted by heating bind to the frame 1 and the electrode 3b on the bottom surface of the LED chip 3 forming eutectic bonds, and most of the solvent resin vaporizes during heating. After the steps above, the LED chip 3 is fixed on the frame 1 by the solidified die-bonding material 5, and are electrically connected to each other.

Then, the electrode 3a of LED chip 3 is wire-bonded with the frame 2. A transparent resin 7 is then poured into the recess la, covering the LED chip 3. Further, the frames 1 and 2 are inserted into a mold containing the transparent resin 6, the transparent resin 6 is solidified, and then the frames 1 and 2 are separated from the mold together with the transparent resin 6 thereby producing the LED device A shown in FIG. 1.

In the LED device A, it is possible to improve the reflectance of the die-bonding material 5 after heat treatment by blending a fine white BN powder in the die-bonding material 5. Hereinafter, the action of the die-bonding material 5 will be described.

In the die-bonding material 5, an epoxy resin having a specific density smaller than that of the solder particles is used as the solvent. Thus, a portion of the solder particles bind to the electrode 3b on the bottom surface of LED chip 3 and to the surface of the frame 1 forming eutectic bonds, and another portion sink to the frame 1 when the die-bonding material 5 is heated in the production process. The ratio of the epoxy resin containing Ag powder and the fine white BN powder increases on the top surface of the die-bonding material 5 when the epoxy resin is evaporated during heating, and thus, the concentration of the fine white BN powder increases on the surface of the die-bonding material 5. The fine white BN powder is white in color and is significantly more reflective of light than Ag, and thus, the reflectance of the region of the die-bonding material 5 close to the surface increases significantly after the heat treatment. Because the die-bonding material 5 is coated on the frame 1 in an area wider than electrode 3b on the bottom surface of the LED chip, the surface of the frame 1 in the region other than that where the LED chip 3 is mounted functions as a reflective plane. It is thus possible to use the light from the LED chip 3 more efficiently by using the die-bonding material 5 according the present preferred embodiment. In addition, BN is superior in heat-releasing efficiency and thus releases the heat rapidly generated when the LED chip 3 is turned on.

In addition, the LED chip 3 is bound to the frame 1 more tightly because the solder particles bind to the electrode 3b on the bottom surface of LED chip 3 and to the surface of frame 1 forming eutectic bonds in the die-bonding material 5 after the heat treatment.

As described above, the die-bonding material 5 connecting the LED chip 3 to the frame 1 after heat treatment is more reflective and is superior in heat-releasing efficiency and in bonding strength. It is thus possible to provide an LED device that is superior in luminous efficiency as well as in the bonding strength and in heat-releasing efficiency by using such a die-bonding material 5.

Although BN is preferably used as the fine white powder in the present preferred embodiment, the reflectance may be improved by adding TiO₂. Other fine white powders may also be used. The content of the die-bonding material may also be altered. For example, the content of the solder particles is adjustable in the range of about 30% to about 40%, and the content of the fine white powder is also adjustable in the range of about 20% to about 40% in a material containing no solder particles. The ratio of Ag powder to the epoxy resin may be properly determined according to the ratio of the solder particles to the fine white powder.

Indium, an indium alloy, or an antimony alloy may also be added to the die-bonding material. Addition thereof lowers the melting temperature of the die-bonding material and the processing temperature, making processing easier. It also leads to improved compatibility of the die-bonding material with the surface of the frame or the bonding pad making it easier to coat the die-bonding material on the frame or bonding pad. Further, it also accelerates the forming of eutectic bonds by the solder particles and improves quality.

The LED device according to the present invention and the method of producing the same are not limited to the preferred embodiments described above. LED devices in which an LED chip is die-bonded on the pad of the frame produced by using the die-bonding material are also included in the scope of the present invention. In addition, methods of producing an LED device including the die bonding step of die-bonding an LED chip on a frame pad are also included in the scope of the present invention.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An LED device comprising:
a frame including a pad;
a die-bonding material;
an LED chip bonded to the pad of the frame with the die-bonding material; wherein
the die-bonding material contains Ag and a fine white powder including BN.

2. The LED device according to claim 1, wherein the fine white powder further includes TiO₂.

3. The LED device according to claim 1, wherein the die-bonding material further includes solder particles.

4. The LED device according to claim 3, wherein the solder particles include one of Sn—Pb, Sn—Ag, and Sn—Ag—Cu.

5. The LED device according to claim 3, wherein the die-bonding material further includes a solvent, the solder particles having a specific density greater than that of the solvent.

6. The LED device according to claim 5, wherein the solvent is an epoxy resin.

7. The LED device according to claim 5, wherein the die-bonding material further includes one of indium, an indium alloy, and an antimony alloy.

8. The LED device according to claim 5, wherein the die-bonding material includes about 40% solder particles, about 36% Ag powder, about 12% fine white BN powder, and the balance the solvent.

9. Amethod of producing an LED device having an LED chip bonded to the pad of a frame with a die-bonding material, wherein the die-bonding material includes Ag powder, a fine white powder, and solder particles in a resin, and the solder particles have a specific density greater than that of the resin, the method comprising:
a step of coating the die-bonding material on the frame in a region larger than a planar size of the LED chip;
a step of mounting the LED chip on the coated die-bonding material; and
a step of heating the die-bonding material to a temperature higher than the melting point of the solder particles.

10. The method according to claim 9, wherein the fine white powder includes BN.

11. The method according to claim 10, wherein the fine white powder further includes TiO₂.

12. The method according to claim 9, wherein the solder particles include one of Sn—Pb, Sn—Ag, and Sn—Ag—Cu.

13. The method according to claim 10, wherein the die-bonding material further includes one of indium, an indium alloy, and an antimony alloy.

14. The method according to claim 10, wherein the die-bonding material includes about 40% solder particles, about 36% Ag powder, about 12% fine white BN powder, and the balance the resin.
